(19) United States
(12) Patent Application Publication
(10) Pub. No.: US 2021/0307580 A1
(43) Pub. Date: Oct. 7, 2021

(54) SYSTEM AND METHOD FOR PROVIDING POWER TO A MOTOR

(71) Applicant: Techtronic Floor Care Technology Limited, Tortola (VG)

(72) Inventor: Jacob Morgan, Huntersville, NC (US)

(21) Appl. No.: 17/351,833

(22) Filed: Jun. 18, 2021

Related U.S. Application Data
(63) Continuation of application No. PCT/US2019/065905, filed on Dec. 12, 2019.
(60) Provisional application No. 62/783,588, filed on Dec. 21, 2018.

(51) Int. Cl. A47L 9/28; A47L 11/40; H02P 27/08; H02P 6/28; H02J 7/00; G01R 19/165; G05F 3/18

(52) U.S. Cl. CPC A47L 9/2842; A47L 9/2889; A47L 11/4011; A47L 9/2857; A47L 9/2831; G05F 3/185; H02P 27/08; H02P 6/28; H02J 7/0063; G01R 19/16538; A47L 9/2884

(57) ABSTRACT

A cleaning system including an energy storage device receptacle, a motor controlled via a motor control circuit, a switch, and a control circuit. The energy storage device receptacle is configured to selectively receive an energy storage device. The switch is electrically connected to the energy storage device receptacle. The switch has an on position and an off position. The control circuit is electrically connected to the switch. The control circuit is configured to output power from the energy storage device to the motor control circuit when the switch is in the on position, and prohibit power from the energy storage device to the motor control circuit when the switch is in the off position.

### CROSS-REFERENCE TO RELATED APPLICATIONS

This application is a continuation of International Patent Application No. PCT/US2019/065905, filed Dec. 12, 2019, which claims priority to U.S. Provisional Patent Application No. 62/783.588, filed Dec. 21, 2018, the entire contents all of which are hereby incorporated by reference herein.

### FIELD

Embodiments relate to cleaning systems.

### SUMMARY

Cleaning systems, such as vacuum cleaners, may be powered via an energy storage device (for example, a rechargeable battery, one or more supercapacitors, etc.). Some cleaning systems may continuously draw power (for example, draw a leakage current) from the energy storage device, even when not in operation. Such a leakage current may lead to under voltage issues.

Thus, one embodiment provides a cleaning system including an energy storage device receptacle, a motor controlled via a motor control circuit, a switch, and a control circuit. The energy storage device receptacle is configured to selectively receive an energy storage device. The switch is electrically connected to the energy storage device receptacle. The switch has an on position and an off position. The control circuit is electrically connected to the switch. The control circuit is configured to output power from the energy storage device to the motor control circuit when the switch is in the on position, and prohibit power from the energy storage device to the motor control circuit when the switch is in the off position.

Another embodiment provides a control circuit including a switch having an open position and a closed position. The control circuit further including circuitry configured to provide power to a motor. The circuitry includes a motor control circuit and a control circuit. The control circuit is electrically connected to the switch. The control circuit includes a power input and a power output. The control circuit is configured to receive power via the power input, output power to the motor control circuit when the switch is in the closed position, and prohibit power to the motor control circuit when the switch is in the open position.

Another embodiment provides a method of providing power to a motor. The method includes receiving, via a power input, power from a power source, and receiving, via a control signal input, an on signal from a switch. The method further includes outputting, via a power output, power to the motor when the on signal is received, receiving, via the control signal input, an off signal from the switch, and prohibiting power to the motor when the off signal is received.

Other aspects of the application will become apparent by consideration of the detailed description and accompanying drawings.

### BRIEF DESCRIPTION OF THE DRAWINGS

FIG. 1A is a perspective view illustrating a cleaning system according to some embodiments.

FIG. 1B is a rear view illustrating the cleaning system of FIG. 1 according to some embodiments.

FIG. 2 is a bottom view illustrating a base of the cleaning system of FIG. 1 according to some embodiments.

FIG. 3 is a block diagram illustrating a control system of the cleaning system of FIG. 1 according to some embodiments.

FIG. 4 is a circuit diagram illustrating a control circuit of the control system of FIG. 3 according to some embodiments.

FIG. 5 is a block diagram illustrating a control system of the cleaning system of FIG. 1 according to some embodiments.

FIG. 6 is a flowchart illustrating a process, or operation, of the cleaning system of FIG. 1 according to some embodiments.

FIG. 7 is a block diagram illustrating a control system of the cleaning system of FIG. 1 according to some embodiments.

FIG. 8 is a circuit diagram illustrating a boost circuit of the control system of FIG. 7 according to some embodiments.

### DETAILED DESCRIPTION

Before any embodiments of the application are explained in detail, it is to be understood that the application is not limited in its application to the details of construction and the arrangement of components set forth in the following description or illustrated in the following drawings. The application is capable of other embodiments and of being practiced or of being carried out in various ways.

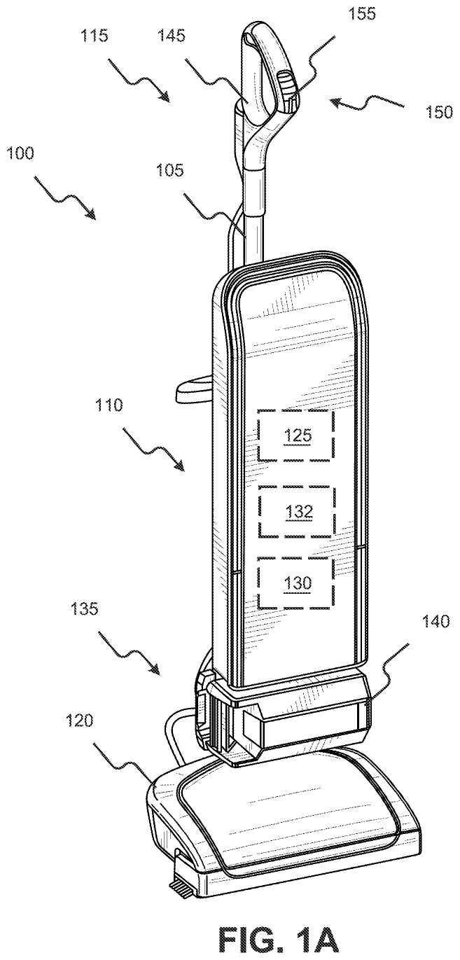

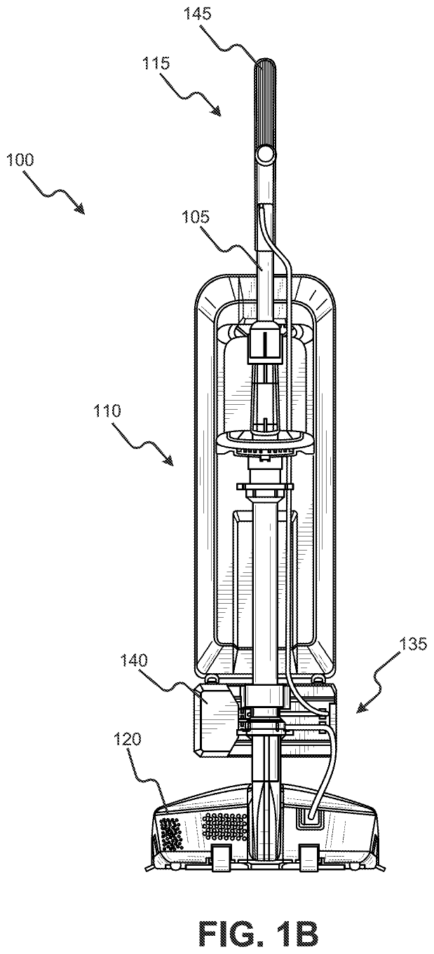

FIGS. 1A and 1B illustrate a cleaning system 100 configured to clean a surface (for example, a floor such as a hardwood floor, a carpeted floor, upholstery, etc.) according to some embodiments. Although illustrated as an upright vacuum cleaner, in other embodiments, the cleaning system 100 may be another type of vacuum, such as but not limited to, a handheld vacuum and a stick vacuum. The cleaning system 100 may include a spine 105, a middle section 110, a handle 115, and a base 120. The spine 105 is coupled (for example, rotatably coupled) to the base 120 and supports the middle section 110 and the handle 115.

The cleaning system 100 includes a suction motor 125 and a dirt receptacle 130. The suction motor 125 may be coupled to a suction source, such as but not limited to, a rotor, or fan, 132. As the suction motor 125 rotates the rotor 132, a suction force is created. The dirt receptacle 130 may be configured to contain debris collected by the cleaning system 100. In some embodiments, the dirt receptacle 130 is a selectively removable receptacle and/or canister. In other embodiments, the dirt receptacle 130 is a removable and replaceable bag.

The cleaning system 100 may further include an energy storage device receptacle 135 configured to releasably receive an energy storage device 140. The energy storage device 140 may be a rechargeable battery having one or more cells connected in series and/or parallel in order to produce a voltage. In some embodiments, the energy storage device 140 may have a chemistry including, but not limited to, an alkaline chemistry, a nickel-cadmium chemistry, a nickel-metal hydride chemistry, and a lithium-ion chemistry. In other embodiments, the energy storage device 140 may be, or include, one or more capacitors (for example, one or more supercapacitors).

The handle 115 may include a grip 145 for a user to grasp. The handle 115 may further include a user-interface 150. In some embodiments, the user-interface 150 includes a button 155 for operating the cleaning system 100.

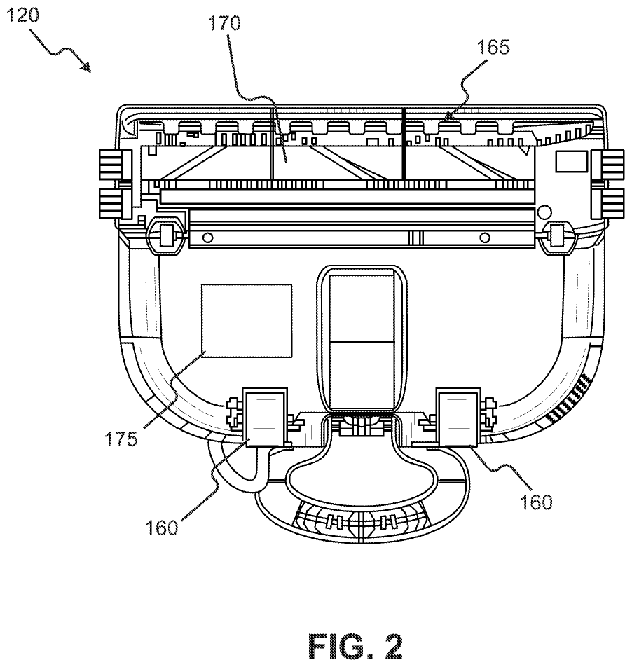

FIG. 2 illustrates a bottom view of the base 120 according to some embodiments. The base 120 may include one or more wheels 160 supporting the system 100 on a surface to be cleaned. The base 120 may further include an inlet 165. After entering though the inlet 165, which may be in fluid communication with suction motor 125, air and/or debris may be drawn into the dirt receptacle 130.

The base 120 may further include a brush roll 170 and a brush roll motor 175. The brush roll 170 is configured to be rotated, by the brush roll motor 175, in order to agitate dirt and/or debris from the cleaning surface.

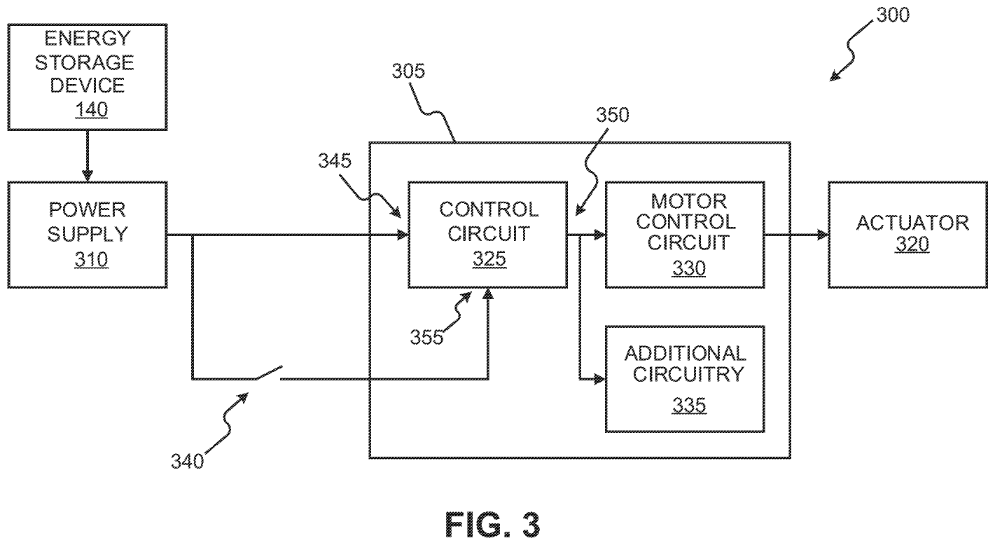

FIG. 3 is a block diagram illustrating a control system 300 of the cleaning system 100 according to some embodiments. The control system 300 includes a controller 305. The controller 305 is electrically and/or communicatively connected to a variety of modules or components of the system 100. For example, the controller 305 is connected to the user-interface 150, a power supply 310, and an actuator 320.

In some embodiments, the controller 305 includes a plurality of electrical and electronic components that provide power, operational control, and protection to the components and modules within the controller 305 and/or the system 100. For example, the controller 305 includes, among other things, a control circuit 325, a motor control circuit 330, and additional circuitry 335.

In some embodiments, the controller 305 further includes an electronic processor (for example, a microprocessor or another suitable programmable device) and memory. The memory includes, for example, a program storage area and a data storage area. The program storage area and the data storage area can include combinations of different types of memory, such as read-only memory (ROM), random access memory (RAM). Various non-transitory computer readable media, for example, magnetic, optical, physical, or electronic memory may be used. The electronic processor is communicatively coupled to the memory and executes software instructions that are stored in the memory, or stored on another non-transitory computer readable medium such as another memory or a disc. The software may include one or more applications, program data, filters, rules, one or more program modules, and other executable instructions. In some embodiments, the control circuit 325, the motor control circuit 330, and the additional circuitry 335 each include separate electronic processors and memory.

The user-interface 150 may be configured to receive input from a user. In some embodiments, the user-interface 150 includes the button 155 and a switch 340. In such an embodiment, the switch 340 is operated by a user via the button 155. In some embodiments, switch 340 is a signal-level, low-current switch, for example, a switch configured for less than 1 ampere current. In other embodiments, the user-interface 150 includes, in addition to or in lieu of button 155, a display (for example, a primary display, a secondary display, etc.), an indicator (for example, a light-emitting diode (LED)), and/or input devices (for example, touch-screen displays, a plurality of knobs, dials, switches, buttons, etc.). The display may be, for example, a liquid crystal display (“LCD”), a light-emitting diode (“LED”) display, an organic LED (“OLED”) display, an electroluminescent display (“ELD”), a surface-conduction electron-emitter display (“SED”), a field emission display (“FED”), a thin-film transistor (“TFT”) LCD, etc.

Power supply, or power source, 310 is configured to supply nominal power to the controller 305 and/or other components of the system 100. As illustrated, in some embodiments, the power supply 310 receives power from the energy storage device 140 and provides nominal power to the controller 305 and/or other components of the system 100. In some embodiments, the power supply 310 may include DC-DC converters, AC-DC converters, DC AC converters, and/or AC-AC converters. In some embodiments, the power supply 310 receives power from a direct-current (DC) power source. In other embodiments, the power supply 310 receives power from an alternating-current (AC) power source (for example, an AC power outlet).

The actuator 320 is configured to actuate a component of the cleaning system 100. In some embodiments, the actuator 320 is the suction motor 125 configured to actuate rotor 132. In other embodiments, the actuator 320 is the brush roll motor 175 configured to actuate brush roll 170. In yet other embodiments, the actuator includes both the suction motor 125 and the brush roll motor 175.

The control circuit, or cutoff circuit, 325 is configured to detect a state of button 155 and/or switch 340 (for example, an ON position and an OFF position). The control circuit 325, based on the state of button 155 and/or switch 340, is further configured to allow power (from power supply 310) to other circuitry and/or components of controller 305 (for example, the motor control circuit 330 and the additional circuitry 335), or disallow power (including leakage current) to the other circuitry of controller 305.

In the illustrated embodiment, the control circuit 325 includes a power input 345, a power output 350, and a control input 355. The control circuit 325 may be configured to receive power (from power supply 310) via the power input 345 and output power (from the power supply 310) via the power output 350. In some embodiments, the control circuit 325 is configured to “pass-through” the power from power supply 310 to the other circuitry and/or components of the control system 300. In other embodiments, the control circuit 325 is configured to convert (for example, to AC-DC conversion, AC-AC conversion, DC-DC conversion, and/or DC-AC conversion) the power from the power supply 310 before outputting the converted power via power output 350. For example, in some embodiments, the control circuit 325 is configured to output approximately 13V via the power output 350.

The control circuit 325 may be further configured to receive a control signal via control input 355. In some embodiments, the control circuit 325 receives the control signal through switch 340. In such an embodiment, the control signal may be, or include, power from power supply 310. For example, in the illustrated embodiment, when switch 340 is in the ON position, power from power supply 310 is provided to control input 355 and when switch 340 is in the OFF position, power from power supply 310 is prohibited to the control input 355. Thus, when switch 340 is in the ON position, a control signal is received by control circuit 325 and control circuit 325 operates (for example, by providing power to other circuitry and/or components of the control system 300), and when switch 340 is in the OFF position, a control signal is not received by control input 355 and control circuit 325 is non-operative (for example, power is prohibited to other circuitry and/or components of the control system 300).

In some embodiments, the control circuit 325 monitors a voltage of the power received via the power input 345. In such an embodiment, when the voltage crosses a predetermined threshold (for example, approximately 26 volts), the control circuit 325 prohibits power to other circuitry and/or components of the control system 300.

The motor control circuit 330 is configured to control the actuator 320. In some embodiments, the motor control circuit 330 provides a pulse-width modulated (PWM) signal having a duty cycle to control the actuator 320. In one embodiment of operation, the motor control circuit 330 receives power (via the control circuit 325) from the power supply 310, converts the power to a PWM signal, and outputs the PWM signal to the actuator 320.

The additional circuitry 335 may include a plurality of electrical and electronic components that provide power, operational control, and/or protection to components and modules within the controller 305 and/or the system 100. In some embodiments, the additional circuitry 335 may include a voltage regulator and/or voltage converter. In some embodiments, the additional circuitry 335 may include one or more sensors configured to sense a plurality of characteristics of the system 100. For example, the one or more sensors may be configured to sense characteristics (such as but not limited to, voltage, current, etc.) of the energy storage device 140 and/or the actuator 320.

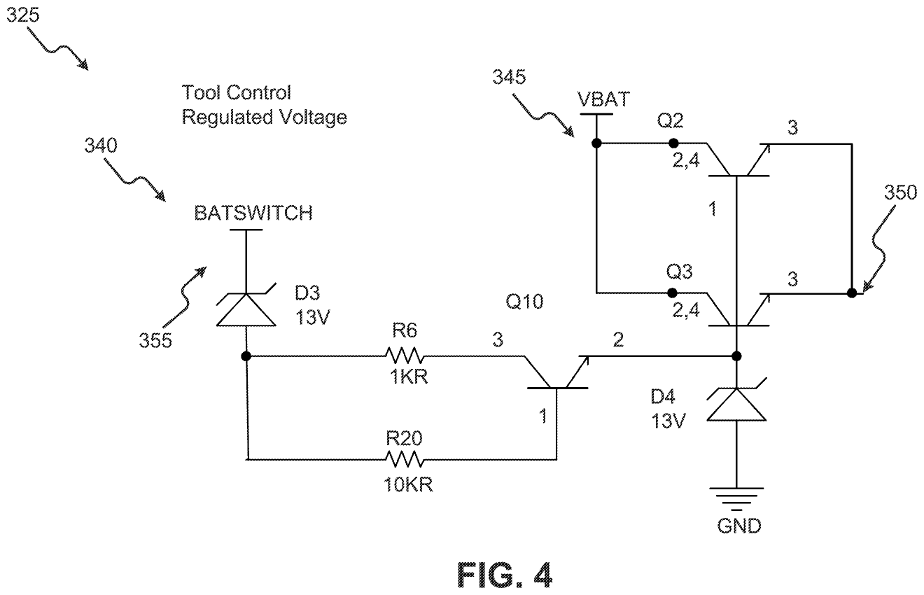

FIG. 4 illustrates a circuit diagram of the control circuit 325 according to some embodiments. In one embodiment of operation, voltage received at control input 355 turns on transistor Q10, thus allowing flow of power. In the illustrated embodiment, when the switch 340 is closed, the voltage of the energy storage device 140 is provided across Zener diodes D3, D4 to turn on the transistor Q10. When the voltage of the energy storage device 140 drops below a Zener voltage, the transistor Q10 turns off and the control circuit 325 prohibits power to other circuitry and/or components of the control system 300, inhibiting over-depletion of the energy storage device. Additionally, in the embodiment illustrated, one or more transistors (for example, BJTs Q2 and Q3) regulate the voltage received at power input 345 before outputting the regulated voltage (for example, at approximately 13V) via the power output 350.

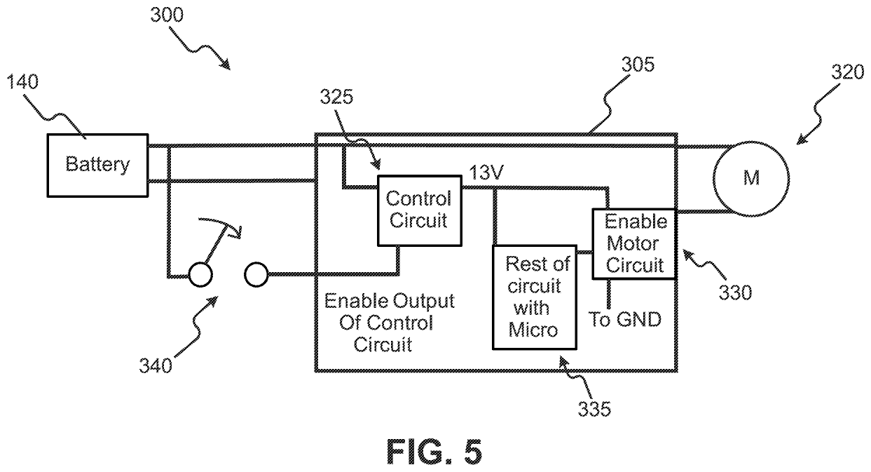

FIG. 5 is a block diagram illustrated control system 300 according to some embodiments. Operation of the control system 300 may be substantially similar to the operation described above. Additionally, such an embodiment may be configured to eliminate leakage current (as described above), while providing a first voltage (for example, 40V) to the actuator 320 and a second voltage (for example, 13V) to the other circuitry and/or components of controller 305 (for example, the motor control circuit 330 and the additional circuitry 335).

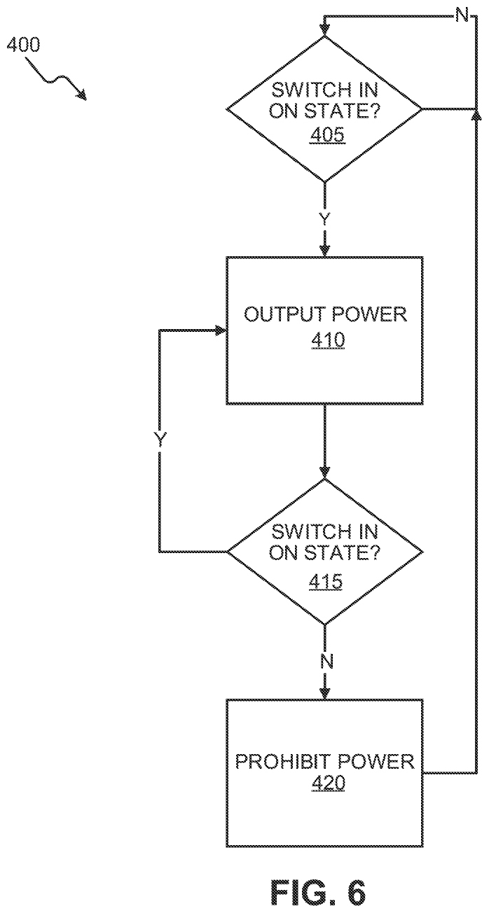

FIG. 6 is a flowchart illustrating a process, or operation, 400 of the cleaning system 100 according to some embodiments. It should be understood that the order of the steps disclosed in process 400 could vary. Furthermore, additional steps may be added and not all of the steps may be required. The control circuit 325 determines if an ON signal has been received (block 405). As discussed above, in some embodiments, the ON signal may be received from user-interface 150. Additionally, as discussed above, in some embodiments the ON signal may be receive through switch 340. In such an embodiment, the ON signal may be produced by the energy storage device 140.

When the ON signal is not received, process 400 cycles back to block 405. When the ON signal is received, the control circuit 325 outputs power to other circuitry and/or components of controller 305 (block 410). As discussed above, in some embodiments, the other circuitry and/or components of the controller 305 includes the motor control circuit 330 and/or the additional circuitry 335. The control circuit 325 determines if the ON signal is being received (block 415).

When the ON signal is still received, process 400 cycles back to bock 410 and control circuit 325 continues to output power to the other circuitry and/or components of controller 305. When the ON signal is not received, power is prohibited from the other circuitry and/or components of controller 305 (block 420). Process 400 then cycles back to block 405.

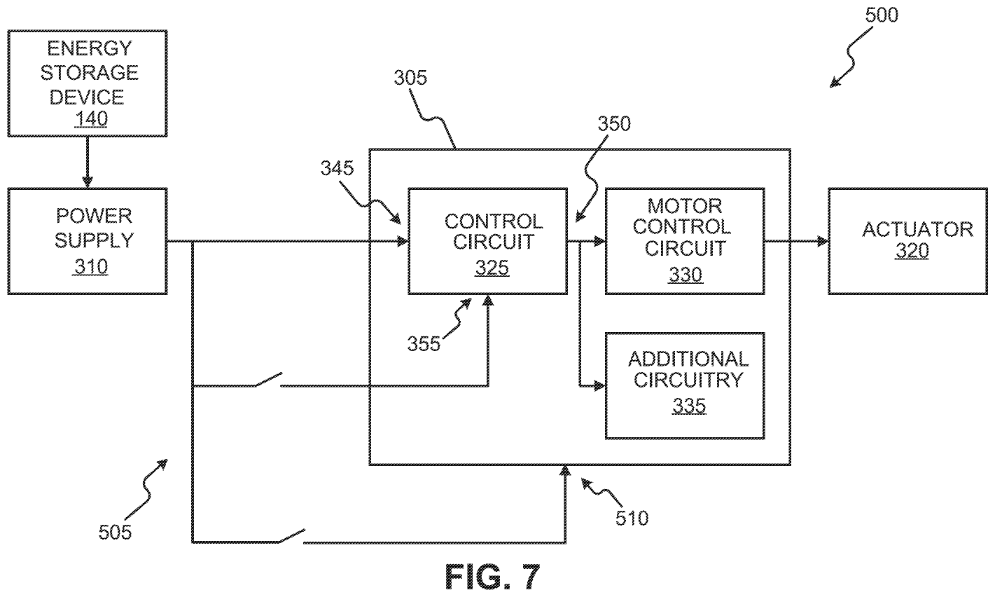

FIG. 7 is a block diagram of a control system 500 according to some embodiments. In some embodiments, control system 500 includes substantially similar components as control system 300. The control system 500 is configured to provide a “boost” to actuator 320 upon receiving a boost input from the user. The control system 500 may include a switch 505 having three positions: (1) an OFF-position; (2) a NORMAL-position; and (3) a BOOST-position. In some embodiments, the switch 505 is a three-position switch. In other embodiments, switch 505 includes two two-position switches. In some embodiments, switch 505 is a signal-level, low-current switch, for example, a switch configured for less than 1 ampere current.

When in the OFF-position, a control signal is not received by control input 355 and control circuit 325 is non-operative (for example, power is prohibited to other circuitry and/or components of the control system 300). When in the NORMAL-position, a control signal is received by control input 355 and control circuit 325 is operative. When in the BOOST-position, the control signal is received by control input 355 and a boost signal is received by a boost input 510 of the controller 305.

Upon receiving the boost signal, controller 305 controls the motor control circuit 330 to operate the actuator 320 at a boost speed. In some embodiments, the boost speed is greater than a normal operating speed of actuator 320. In some embodiments, the motor control circuit 330 operates the actuator 320 at the boost speed by increasing a duty cycle of the PWM signal supplied to the actuator 320.

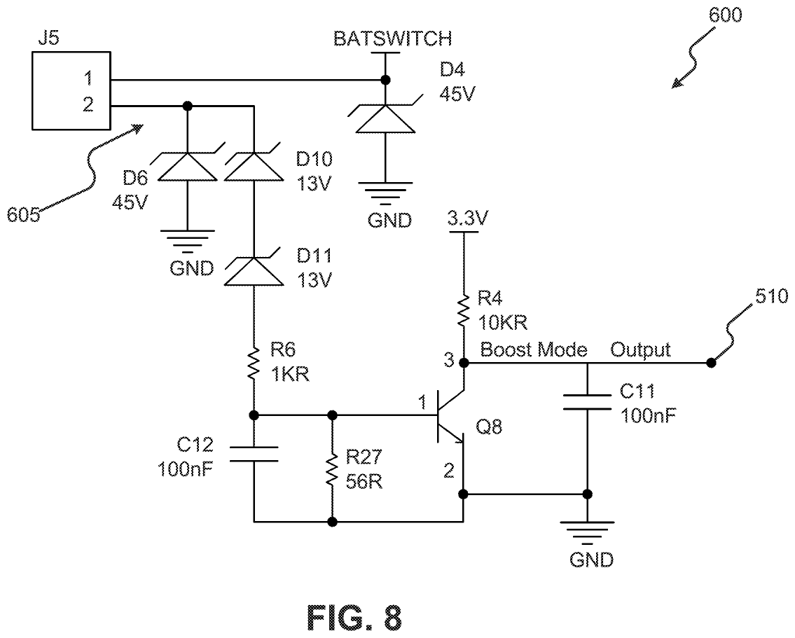

FIG. 8 is a circuit diagram of a boost circuit 600 according to some embodiments. In the illustrated embodiment, boost circuit 600 includes, among other things, an input 605, Zener diodes D10, D11, and transistor Q8. In operation, when switch 505 is in the BOOST-position, voltage from energy storage device 140 is received at input 605 and provided across Zener diodes D10, D11 to turn on transistor Q8, thus supplying the boost signal to boost input 510 of controller 305. When the voltage of the energy storage device 140 drops below a Zener voltage of Zener didoes D10, D11, the transistor Q8 turns off and the boost signal is not received at the boost input 510 of controller 305.

Embodiments provide, among other things, a system and method for providing power to a motor. Various features and advantages of the application are set forth in the following claims.

What is claimed is:

1. A cleaning system comprising:
an energy storage device receptacle configured to selectively receive an energy storage device;
a motor controlled via a motor control circuit;
a switch electrically connected to the energy storage device receptacle, the switch having an on position and an off position; and
a control circuit electrically connected to the switch, the control circuit configured to
output power from the energy storage device to the motor control circuit when the switch is in the on position, and
prohibit power from the energy storage device to the motor control circuit when the switch is in the off position.

2. The cleaning system of claim 1, wherein the motor control circuit controls the motor via a pulse-width modulated signal.

3. The cleaning system of claim 1, wherein the motor is a suction motor.

4. The cleaning system of claim 1, wherein the motor is a brush roll motor.

5. The cleaning system of claim 1, wherein the control circuit is further configured to provide power to a control system of the cleaning system when the switch is in the on position.

6. The cleaning system of claim 1, wherein the control circuit is further configured to prohibit power to the motor control circuit when a voltage of the energy storage device crosses a predetermined threshold.

7. The cleaning system of claim 1, wherein the switch is a signal-level, low-current switch.

8. The cleaning system of claim 1, wherein the switch further has a boost position.

9. The cleaning system of claim 8, wherein when in the boost position, the motor operates at a boost speed, wherein the boost speed is greater than a normal operating speed.

10. A control circuit comprising:
a switch having an open position and a closed position;
circuitry configured to provide power to a motor, the circuitry including a motor control circuit and a control circuit, the control circuit electrically connected to the switch, the control circuit including a power input and a power output, the control circuit configured to
receive power via the power input,
output power to the motor control circuit when the switch is in the closed position, and
prohibit power to the motor control circuit when the switch is in the open position.

11. The control circuit of claim 10, wherein the motor control circuit provides power to the motor via a pulse-width modulated signal.

12. The control circuit of claim 10, wherein the control circuit is further configured to output power to additional circuitry when the switch is in the closed position.

13. The control circuit of claim 10, wherein power is provided from an energy storage device.

14. The control circuit of claim 10, wherein the motor is a suction motor of a cleaning system.

15. The control circuit of claim 10, wherein the motor is a brush roll motor of a cleaning system.

16. The control circuit of claim 10, wherein the circuitry further includes a Zener diode and a transistor.

17. The control circuit of claim 16, wherein the Zener diode has a Zener voltage, and the control circuit is configured to prohibit power, via the transistor, to the motor control circuit when a voltage received at the power input is less than the Zener voltage.

18. A method of providing power to a motor, the method comprising:
receiving, via a power input, power from a power source;
receiving, via a control signal input, an on signal from a switch;
outputting, via a power output, power to the motor when the on signal is received;
receiving, via the control signal input, an off signal from the switch; and
prohibiting power to the motor when the off signal is received.

19. The method of claim 18, wherein the power is provided to the motor via a motor control circuit.

20. The method of claim 19, wherein the motor control circuit provides power to the motor via a pulse-width modulated signal.

21. The method of claim 18, wherein the power source is a rechargeable battery.

22. The method of claim 21, further comprising:
prohibiting power to the motor when a voltage of the power source crosses a predetermined threshold.

23. The method of claim 19, wherein the predetermined threshold is a Zener voltage set by a Zener diode.

24. The method of claim 18, wherein the motor is a suction motor of a cleaning system.

25. The method of claim 18, wherein the motor is a brush roll motor of a cleaning system.

26. The method of claim 18, further comprising:
providing power to a control system when the on signal is received.
